(19) United States
(12) Patent Application Publication
(10) Pub. No.: US 2026/0005671 A1
(43) Pub. Date: Jan. 1, 2026

(54) LAMÉ MODE RESONATOR WITH ALUMINUM NITRIDE (AlN) MIRROR LAYER

(71) Applicant: RF360 Singapore Pte. Ltd., Republic Plaza (SG)

(72) Inventor: Ralph DURNER, München (DE)

(21) Appl. No.: 18/759,634

(22) Filed: Jun. 28, 2024

(51) Int. Cl. H03H 9/17; H03H 3/02; H03H 9/02; H03H 9/54

(52) U.S. Cl. CPC H03H 9/175; H03H 3/02; H03H 9/02015; H03H 9/54

(57) ABSTRACT

Aspects include devices and methods for a resonator with an aluminum nitride mirror layer. Some aspects may include an aluminum nitride layer formed on or above a substrate, an electrode layer formed on or above the aluminum nitride layer opposite the substrate, a piezoelectric layer formed on the electrode layer, and an interdigital transducer formed on the piezoelectric layer.

### FIELD

The present disclosure relates generally to wireless communications, and in particular to high-frequency filters that can be implemented with electroacoustic resonators.

### BACKGROUND

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering high-frequency (e.g., generally greater than 100 MHz) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices such as cellular phones).

### SUMMARY

Aspects of the present disclosure describe electroacoustic devices. In some aspects, the techniques described herein relate to an electroacoustic structure including: a substrate; an aluminum nitride layer formed on or above the substrate; and electrode layer formed on or above the aluminum nitride layer opposite the substrate; a piezoelectric layer formed on the electrode layer; and an interdigital transducer formed on the piezoelectric layer.

In some aspects, the techniques described herein relate to an electroacoustic structure, wherein the piezoelectric layer includes a crystalline structure selected to excite Lamé mode resonance.

In some aspects, the techniques described herein relate to an electroacoustic structure, wherein the piezoelectric layer further includes aluminum scandium-30 nitride (AlSc30N).

In some aspects, the techniques described herein relate to an electroacoustic structure, wherein the electroacoustic structure has a resonance frequency between 3 gigahertz (GHz) and 8 GHz.

In some aspects, the techniques described herein relate to an electroacoustic structure, wherein the aluminum nitride layer has a thickness approximately equal to a wavelength of the resonance frequency.

In some aspects, the techniques described herein relate to an electroacoustic structure, wherein the interdigital transducer includes a plurality of copper (Cu) electrode fingers.

In some aspects, the techniques described herein relate to an electroacoustic structure, wherein the electrode layer includes molybdenum (Mo).

In some aspects, the techniques described herein relate to an electroacoustic structure, further including a silicon oxide (SiO2) layer formed between the aluminum nitride layer.

In some aspects, the techniques described herein relate to an electroacoustic structure, wherein: the electroacoustic structure is a resonator of a filter circuit within a wireless transceiver of a wireless communication device; and the filter circuit is electrically coupled to an antenna of the wireless communication device.

In some aspects, the techniques described herein relate to a method of fabricating an electroacoustic structure, the method including: fabricating a silicon substrate; forming an aluminum nitride layer on the silicon substrate; and fabricating an electroacoustic stack on or above the aluminum nitride layer, the electroacoustic stack including a piezoelectric layer different from the aluminum nitride layer and a interdigital transducer, wherein the piezoelectric layer includes a crystalline structure configured to excite a plate mode resonance.

In some aspects, the techniques described herein relate to a method, wherein fabricating the piezoelectric stack includes fabricating a lower interdigital transducer on the aluminum nitride layer; forming the piezoelectric layer on or above the lower interdigital transducer; and forming an upper interdigital transducer on the piezoelectric layer, where the interdigital transducer includes the upper interdigital transducer and the lower interdigital transducer.

In some aspects, the techniques described herein relate to a method, wherein fabricating the electroacoustic stack further includes: forming a silicon dioxide (SiO2) layer between the piezoelectric layer and the silicon substrate; and forming an electrode layer between the SiO2 layer and the piezoelectric layer.

In some aspects, the techniques described herein relate to a method, wherein the piezoelectric layer further includes aluminum scandium-30 nitride (AlSc30N); and wherein the electroacoustic structure has a resonance frequency between 3 gigahertz (GHz) and 8 GHz.

In some aspects, the techniques described herein relate to a method, wherein the aluminum nitride layer is formed with a thickness approximately equal to a wavelength of the resonance frequency; and wherein the electrode layer includes molybdenum (Mo).

In some aspects, the techniques described herein relate to an electroacoustic structure including: a substrate; an aluminum nitride layer formed on or above the substrate; a electroacoustic stack formed on or above the aluminum nitride layer, the electroacoustic stack including a piezoelectric layer different from the aluminum nitride layer and a interdigital transducer, the piezoelectric layer includes a crystalline structure configured to excite a plate mode resonance.

In some aspects, the techniques described herein relate to an electroacoustic structure, wherein the electroacoustic stack further includes a silicon dioxide (SiO2) layer formed between the piezoelectric layer and the substrate.

In some aspects, the techniques described herein relate to an electroacoustic structure, further including an electrode layer formed between the SiO2 layer and the piezoelectric layer.

In some aspects, the techniques described herein relate to an electroacoustic structure, wherein the piezoelectric layer further includes aluminum scandium-30 nitride (AlSc30N); and wherein the electrode layer includes molybdenum (Mo).

In some aspects, the techniques described herein relate to an electroacoustic structure, wherein the interdigital transducer of the electroacoustic stack includes a top interdigital transducer formed on or above the piezoelectric layer and a lower interdigital transducer formed under or below the piezoelectric layer.

In some aspects, the techniques described herein relate to an electroacoustic structure, wherein a dielectric material is positioned between electrode fingers of the lower interdigital transducer.

In some aspects, the apparatuses described above can include a mobile device with a camera for capturing one or more pictures. In some aspects, the apparatuses described above can include a display for displaying one or more pictures. This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and embodiments, will become more apparent upon referring to the following specification, claims, and accompanying drawings.

### BRIEF DESCRIPTION OF THE DRAWINGS

FIG. 1 is a diagram of an example of an electroacoustic device.

FIG. 2A illustrates a device layer stack for an electroacoustic device in accordance with aspects described herein.

FIG. 2B illustrates a device layer stack for an electroacoustic device in accordance with aspects described herein.

FIG. 2C illustrates a device layer stack for an electroacoustic device in accordance with aspects described herein.

FIG. 2D illustrates a device layer stack for an electroacoustic device in accordance with aspects described herein.

FIG. 2E illustrates a device layer stack for an electroacoustic device in accordance with aspects described herein.

FIG. 3 illustrates a perspective of an electroacoustic device including a Lamé mode acoustic stress profile in accordance with aspects described herein.

FIG. 4 illustrates details of a Lamé mode acoustic stress profile in accordance with aspects described herein.

FIGS. 5A-D illustrate aspects of performance for an electroacoustic device in accordance with aspects described herein.

FIGS. 6A-D illustrate aspects of performance for an electroacoustic device in accordance with aspects described herein.

FIG. 7 is a flowchart illustrating a method of fabricating an electroacoustic resonator in accordance with aspects described herein.

FIG. 8 is a diagram of an environment that includes a wireless communication device that can include a resonator with harmonic suppression for improved performance, in accordance with aspects described herein.

FIG. 9 illustrates a transceiver path that can include an electroacoustic resonator with harmonic suppression, in accordance with aspects described herein.

### DETAILED DESCRIPTION

The detailed description set forth below in connection with the appended drawings is intended as a description of exemplary implementations and is not intended to represent the only implementations in which the invention may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

Electroacoustic devices such as surface acoustic wave (SAW) and bulk acoustic wave (BAW) resonators, which employ electrode structures on a surface of a piezoelectric material, are being designed to cover more frequency ranges (e.g., 500 MHz to 6 GHz and beyond), to have higher bandwidths (e.g., up to 25%), and to have improved efficiency and performance as designs using such devices become more complex. Additionally, such devices can be included in systems that support transmission, reception, and multiple channels at different frequencies within the same wireless communication apparatus.

Current communication devices use SAW devices at frequencies around or below 3 GHz, while BAW devices are used above 3 GHz. Existing BAW devices, however, are expensive to produce, while providing high performance at frequencies above 3 GHz. Aspects described herein provide acceptable performance above 3 GHz for many applications, at a cost (e.g., due to materials and simplified manufacturing) improvement over existing BAW devices that operate at these frequencies (e.g., 3 GHz to 6 GHz, and possibly up to and around 10 GHz).

Lamé mode refers to a particular resonance wave mode that is possible with piezoelectric electroacoustic devices. Such devices are configured with a particular crystalline cut of the piezoelectric material for a “plate mode” guided within a devices layer (e.g., as compared with SAW devices where waves are guided on a device surface). A plate mode describes an acoustic lateral Eigenmode in a thin, finite plate. A Lamé mode is one type of plate mode. Lamé modes exit over multiple layer stacks within a device as detailed below. A simplest Lamé mode is a wave mode between adjacent electrode fingers which function as a rotating mode within or across a piezoelectric layer. The Lamé mode waves are waves associated with acoustic pressure and associated molecule displacement within the device layers caused by the acoustic pressure. Such waves travel along tracks guided by electrode fingers of an IDT of a device.

Various aspects herein refer to plate mode excitation or Lamé mode excitation. Such aspects can apply to either Lamé mode or plate mode operations depending on the particular orientation and configuration of a stack.

SAW devices hit performance limits due to surface wave qualities at around 3 GHz, while BAW devices hit performance limits at frequencies between 6-10 GHz, depending on device structures. BAW devices with propagation within material layers suffer losses due to energy entering a substrate. SAW devices with surface wave propagation do not suffer similar losses. In order to mitigate such losses from signals radiating into a substrate, mirror layers can be used in BAW or plate mode devices (such as Lamé mode devices). Such mirror layers, however, add significant additional costs to resonator devices.

Aspects described herein describe a Lamé mode device structure on a simple AlN mirror layer. An AlN mirror layer with a high associated acoustic velocity can provide acceptable device performance at significantly reduced costs relative to a typical multi-layer mirror stack on a silicon substrate or relative to substrate materials with higher acoustic velocities (e.g., greater than approximately 6000 meters per second (m/s)) which mitigate substrate losses (e.g., sapphire, diamond, etc.).

Aspects described herein are compatible with silicon waver as carrier (SMR) fabrication processes, providing high quality manufacturing processes, mitigating decreased performance characteristics compared to devices with higher manufacturing costs (e.g., sapphire or diamond substrates, etc.).

Additional details are provided in the context of the figures below.

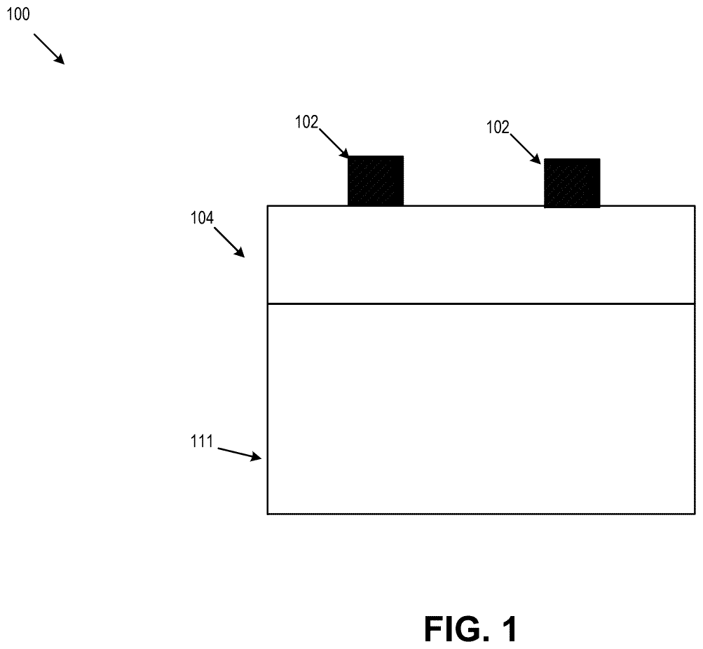

FIG. 1 is a diagram of a cross section from an example of an electroacoustic device 100. The electroacoustic device 100 may be configured as or be a portion of a resonator. In certain descriptions herein, the electroacoustic device 100 may be referred to as a bulk acoustic wave (BAW) resonator or a thin film bulk acoustic resonator (TFBAR). In other aspects, the electroacoustic device 100 can be combined with elements of surface acoustic wave (SAW) resonators, for example, when filtering is being performed on different frequency bands in the same filter. The electroacoustic device 100 includes an electrode structure 102, that may be referred to as an interdigital transducer (IDT), on the surface of a piezoelectric material 104. The electrode structure 102 generally includes first and second comb shaped electrode structures (conductive and generally metallic) with electrode fingers extending from two busbars towards each other arranged in an interlocking manner in between two busbars (e.g., arranged in an interdigitated manner). An electrical signal excited in the electrode structure 102 (e.g., applying an AC voltage) is transformed into an acoustic wave that propagates through the piezoelectric material 104. The acoustic wave is transformed back into an electrical signal in the electrode structure 102 and provided as an output. In many applications, the piezoelectric material 104 has a particular crystal orientation such that when the electrode structure 102 is arranged relative to the crystal orientation of the piezoelectric material 104, the acoustic wave mainly propagates in a direction perpendicular to the direction of the fingers (e.g., parallel to the busbars). In various examples, circuits described herein having such structures can include micro-electroacoustic filters implemented with micro-electromechanical structure (MEMS) technology. MEMS technology includes miniature physical structures that can have both mechanical (e.g., vibrational or acoustic) component characteristics as well as electrical characteristics. In some examples, the resonators described herein can be built using MEMS fabrication techniques to generate structures with dimensions less than one micrometer.

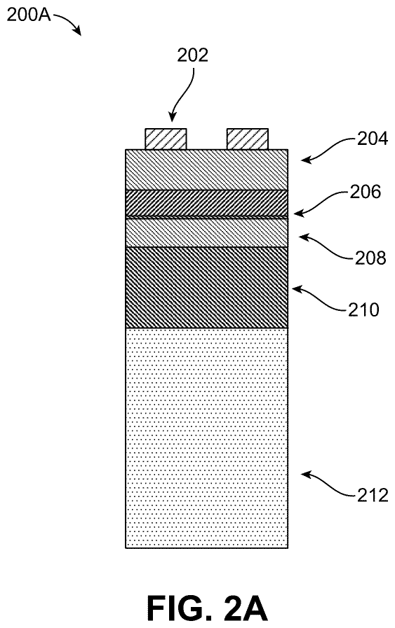

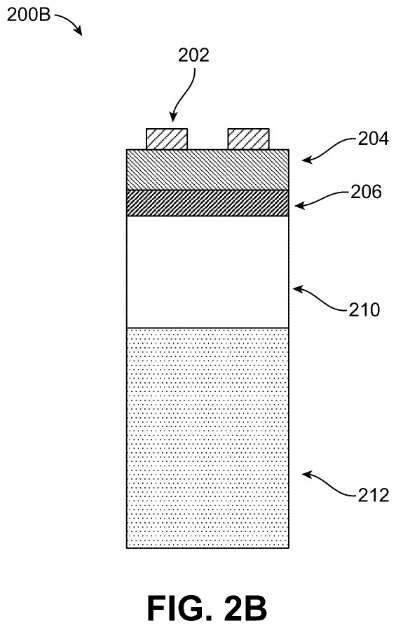

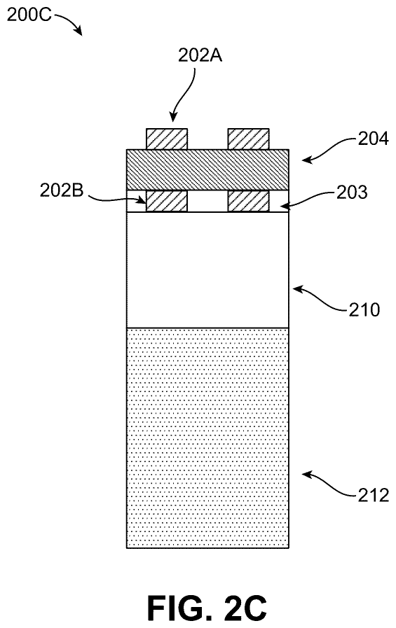

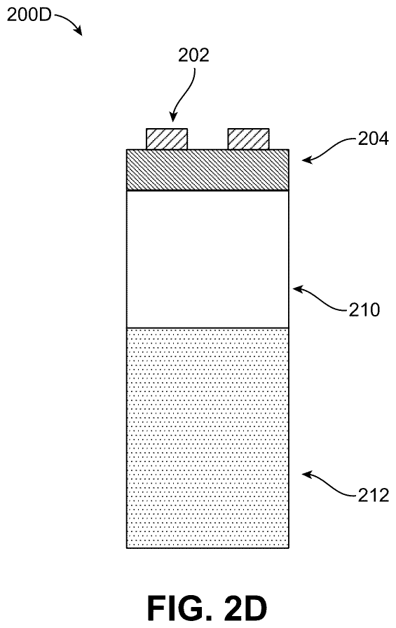

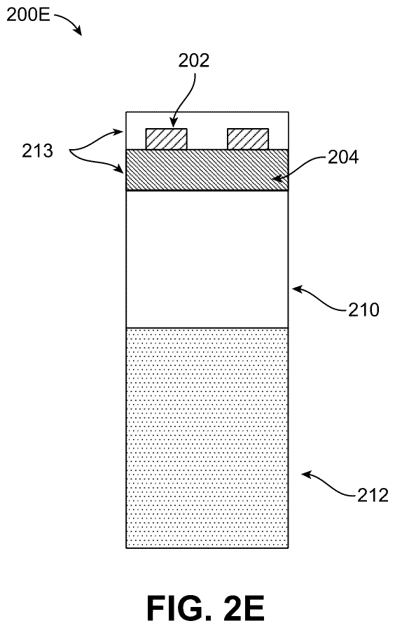

In FIG. 1, the electroacoustic device 100 is illustrated by a simplified layer stack including a piezoelectric material 104 with an electrode structure 102 disposed on the piezoelectric material 104. The electrode structure 102 is conductive and generally formed from metallic materials. The piezoelectric material may be formed from a variety of materials such as quartz, lithium tantalate (LiTaO3), lithium niobate (LiNbO3), doped variants of these, or other piezoelectric materials. For Lamé mode resonators in accordance with aspects described herein, aluminum scandium nitrate (AlScN) can be used as the piezoelectric material. The device 100 is further illustrated with supporting layers 111. Additional details of supporting layers 111 are described in FIGS. 2A and 2B below. It should be appreciated that more complicated layer stacks including layers of various materials may be possible within the stack. In some implementations, the piezoelectric material 104 may be extended with multiple interconnected electrode structures disposed thereon to form a multi-resonator filter or to provide multiple filters. While not illustrated, when provided as an integrated circuit component, a cap layer may be provided over the electrode structure 102. The cap layer is applied so that a cavity is formed between the electrode structure 102 and an under surface of the cap layer. Electrical vias or bumps that allow the component to be electrically connected to connections on a substrate (e.g., via flip-chip or other techniques) may also be included.

FIG. 2A illustrates a device layer stack 200A for an electroacoustic device in accordance with aspects described herein. The device layer stack 200A includes a silicon (Si) substrate 212 as a base material substrate for the device layer stack 200A. As indicated above, using a Si substrate compatible with silicon waver as carrier (SMR) fabrication processes improves device desirability by providing a high-quality manufacturing ecosystem which can mitigate decreased performance characteristics compared to devices with higher manufacturing costs (e.g., sapphire or diamond substrates, etc.). The use of silicon SMR devices can provide low-cost devices with acceptable performance for many applications, making devices in accordance with aspects described herein preferable to higher performance devices with higher associated costs, so long as basic performance criteria are met.

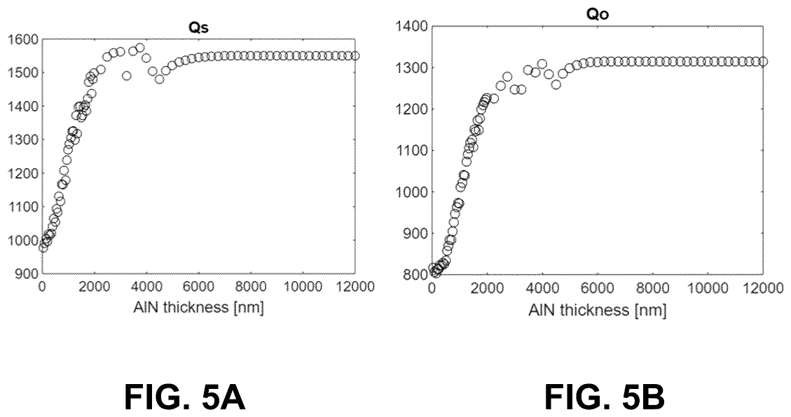

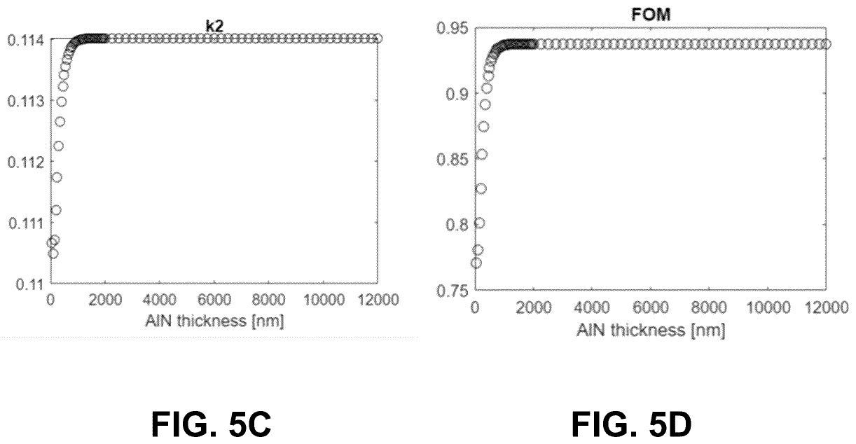

The device layer stack 200A further includes an aluminum nitride (AlN) mirror layer 210. In an aspect, the AlN mirror layer 210 may be a single mirror layer. The use of a single mirror layer 210 with a high acoustic velocity can mitigate energy losses from the above resonator layers transferring energy into the silicon substrate 212, with comparably less thickness, material, and associated cost than previously known multi-layer mirror stacks. Such a single layer mirror avoids additional modes that can occur within and between the layers of a multi-layer mirror, and further enables the use of a low-cost high efficiency silicon substrate instead of very high cost high acoustic-velocity substrate wafer materials like sapphire. AlN can be sputtered on top of the silicon substrate 212 using known manufacturing processes during fabrication to thicknesses sufficient to provide acceptable performance values for key resonator parameters (e.g., Qs, Qo, k2, and FOM, as detailed further below in FIGS. 5A-D and 6A-D).

The device layer stack 200A further includes layers 204, 206, and 208 with IDT 202 to generate Lamé mode signals. The IDT 202 is formed in a metallization layer on or above the piezoelectric layer 204. The piezoelectric layer 204 is formed on or above a silicon dioxide (SiO2) layer 208 and an electrode layer 206. The SiO2 layer 208 is an optional layer that is included to store energy and improve resonance characteristics along with the electrode layer 206. During operation, opposite electrical signals are provided on adjacent fingers (e.g., shown as cross sections of the adjacent fingers of the IDT 202) creating an electrical field through the piezoelectric layer 204 which excites the associated stress in the material of the piezoelectric layer 204 resulting in material displacement and acoustic waves within the layers stack 200A. The presence of the electrode layer 206 shapes the electrical field and associated acoustic wave, stopping the electrical field from extending into the substrate. Part of the energy from the associated acoustic waves is stored within the electrode layer and the SiO2 layer, further shaping and tuning device resonance performance and frequencies. The SiO2 layer can be adjusted or omitted as part of the selection of device performance and frequency (e.g., resonance) selection.

FIG. 2B illustrates a device layer stack 200B for an electroacoustic device in accordance with aspects described herein. The device layer stack 200B includes the same structure as the device layer stack 200A, but with the optional SiO2 layer 208 omitted. As illustrated, the device layer stack 200B includes the IDT 202 layer formed on or above the piezoelectric layer 204, and the piezoelectric layer 204 formed on the electrode layer 206. The IDT 202, the piezoelectric layer 204, and the electrode layer 206 can form the core Lamé mode resonator structure, with the layers below considered supporting layers (e.g., supporting layers 111). The supporting layers include the mirror layer 210 and the substrate 212.

In accordance with aspects described herein, the IDT 202 can be formed in a metallization layer made of copper (Cu) or any other such conductive material. Similarly, the electrode layer 206 can be formed of molybdenum (Mo), which provides an effective base for fabrication of the piezoelectric layer.

Additional implementations can further modify the layer stacks described above depending on particular performance targets for a given implementation. FIG. 2C illustrates a device layer stack 200C for an electroacoustic device in accordance with aspects described herein. The device layer stack 200C is similar to the device layer stacks above, but the electrode layer 206 is replaced by a second metallization layer 203 comprising a lower IDT 202B with the IDT on the piezoelectric layer 204 operating as an upper IDT 202A. Gaps between fingers of the lower IDT 202B in the layer 203 can be air gaps, or can be filled with a dielectric material. Just as above, the IDTs 202A and 202B can be made of Cu or any other such suitable metallization layer. FIG. 2D illustrates a device layer stack 200D for an electroacoustic device in accordance with aspects described herein. In the implementation of the device layer stack 200D, the electrode layer 206 is omitted. In this case, the device layer stack 200D of FIG. 2D includes an electrode layer 202 (e.g., IDT), piezoelectric layer 204 with one or more properties (e.g., crystalline structure and the like) configured to excite a Lamé mode, AlN mirror layer 210, and substrate 212.

In general, various layer stacks may also possible. In such a case a device layer stack according with the principles described herein may include more generally as illustrated by FIG. 2E an electroacoustic structure 200E including a substrate 212 (e.g., potentially silicon or the like, an aluminum nitride layer 210 formed on or above the substrate 212, and a electroacoustic stack 213 formed on or above the aluminum nitride layer 210, the electroacoustic stack 213 including a piezoelectric layer 204 different from the aluminum nitride layer 210 and a interdigital transducer 202. The piezoelectric layer 204 includes a crystalline structure configured to excite a plate mode resonance. In other implementations, the electrode stack 213 can include additional or alternative layers, including gap layers, additional metallization layers for additional IDTs, or any other such configuration to support the excitation of the plate mode resonance.

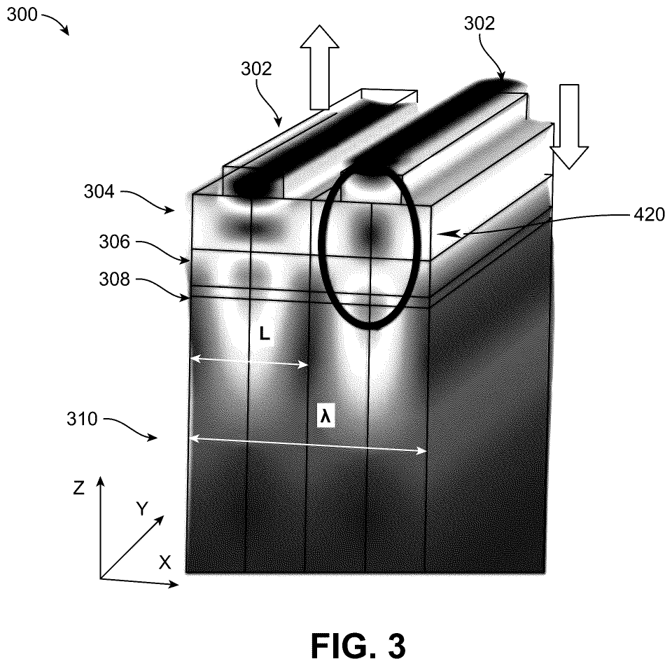

FIG. 3 illustrates a perspective 300 of an electroacoustic device including a Lamé mode acoustic stress profile in accordance with aspects described herein. The perspective 300 shows the same material stack layer as the material layer stack 200A of FIG. 2A. The material stack of the perspective 300 shows copper fingers of an IDT 302 formed on top of an aluminum scandium-30 nitride (AlSc30N) piezoelectric layer 304. The piezoelectric layer 304 is formed on Mo used for the electrode layer 306. The Mo electrode layer 306 is formed on a SiO2 layer 308. The SiO2 layer is formed on an Aluminum Nitride (AlN) mirror layer 310. The AlN mirror layer 310 reflects energy from the above piezoelectric stack that would otherwise be lost into the Si substrate layer (not shown) below the AlN mirror layer 310. The reflected energy joins with the Lamé mode wave energy. The above layers are all formed on silicon (Si) of the substrate layer (not shown in FIG. 3).

The electrode fingers of the IDT 302 are separated by a pitch distance L, and result in an acoustic wave having a length 2, which is twice L. The shading of the perspective 300 shows the pressure (e.g., and associated displacement) from an electrical signal that creates opposite polarity voltages on the adjacent fingers of the IDT 302 at peaks of a communication signal. These signals and associated voltage differences create fields within the layers of the illustrated device stack, resulting in stress and associated material displacement which creates the illustrated Lamé mode acoustic wave within the materials.

In accordance with aspects described herein, AlSc30N can be used as the piezoelectric layer and orientation that provides Lamé mode acoustic waves and device resonances at frequencies suitable for 3-6+ GHz device resonance. Perspective 420 provides additional detail of the wave pattern within the device stack for the illustrated AlSc30N Lamé mode resonator device.

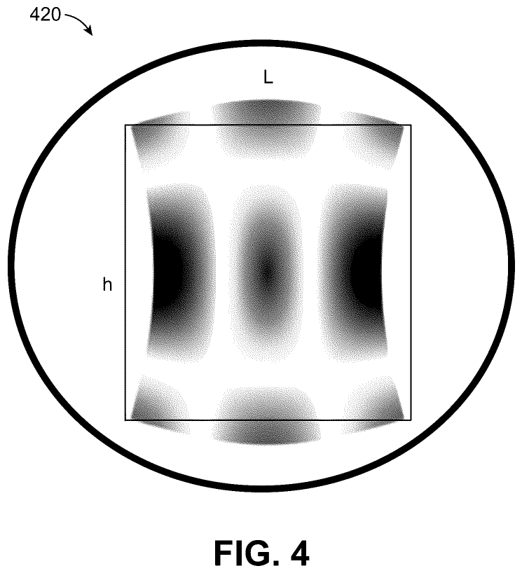

FIG. 4 illustrates details of a Lamé mode acoustic stress profile of perspective 420 in accordance with aspects described herein. The illustrated stress profile in perspective 420 is half of the Lame mode wave (e.g., with the other half of the wave below the adjacent electrode finger of the IDT 302), and the wave will propagate along the IDT 302 as the electrical signals on the IDT 302 vary. The illustrated Lamé mode stress profile in perspective 420 shows the stress profile across the piezoelectric layer 304 and electrode layer 306, and into supporting layers, which include the SiO2 layer 308 and mirror layer 310, and the top of the Si substrate layer (e.g., similar to the substrate 212, but not shown in FIG. 3). As illustrated, the presence of a mirror layer (e.g., the AlN layer 310) operates to reflect energy that would otherwise be lost into the Si substrate layer back into the Lamé mode wave energy (e.g., resulting in the stress profile pattern from acoustic energy in the Lamé mode(s)) present across the piezoelectric layer 304.

FIGS. 5A-D illustrate aspects of performance for an electroacoustic device in accordance with aspects described herein. The charts illustrated in FIGS. 5A-D are associated with an example device having an L value equal to 2 micrometers (um) and a λ of 4 um. Each chart shows a different key resonator parameter value on the y-axis charted against increasing mirror layer thicknesses (e.g., AlN mirror layers 210, 310, etc.) on the x-axis. As illustrated, the performance values increase drastically up to a thickness of the mirror layer equal to L, and peak approximately at λ or just below λ.

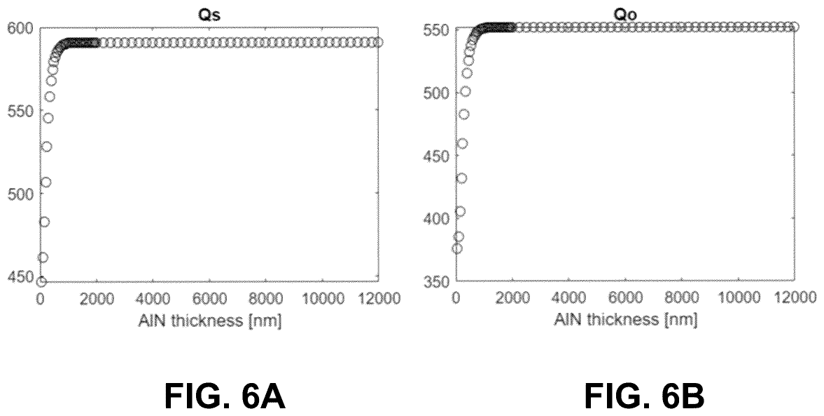

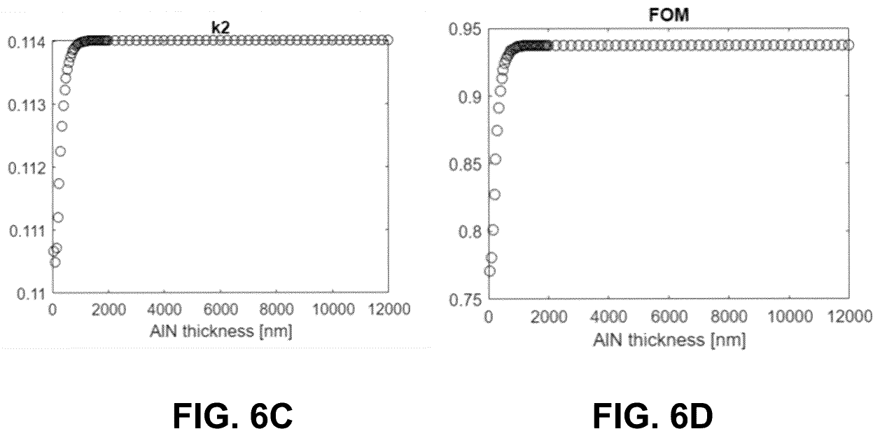

FIGS. 6A-D illustrate aspects of performance for an electroacoustic device in accordance with aspects described herein. The charts of FIGS. 6A-D correspond to similar charts for FIGS. 5A-D but for a device with a different design. The charts illustrated in FIGS. 6A-D are associated with an example device having an L value equal to 0.5 micrometers (um) and a λ of 1 um.

Table 1 below illustrates a comparison of the performance parameters detailed above in FIGS. 5A-D and FIGS. 6A-D, but for alternate materials instead of for different thicknesses of the AlN mirror layer in accordance with aspects described herein.

TABLE 1

| | Qs | Qp | K² | FOM |
|---|---|---|---|---|
| No substrate | 1480 | 1300 | 13.5% | 1.73 |
| Si substrate | 1000 | 830 | 11.0% | 1.14 |
| Al2O3 substrate | 1580 | 1300 | 11.0% | 1.43 |
| 2000 nm AlN on Si | 1530 | 1220 | 10.9% | 1.39 |

As illustrated, the use of an AlN mirror layer on a Si substrate improve the performance when compared to the use of the Si substrate alone without a mirror layer to levels comparable to other configurations, but using a material structure compatible with repeatable device manufacturability and implementation performance (e.g., compared with an expensive Al2O3 process or an impractical no substrate device).

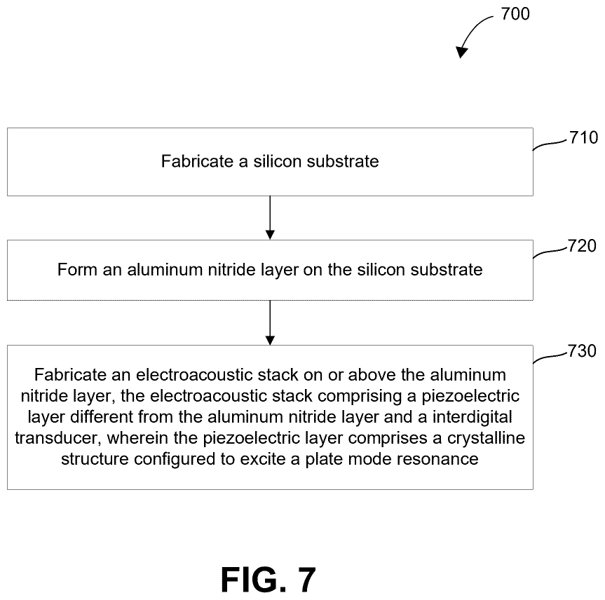

FIG. 7 illustrates a method 700 for fabricating a resonator in accordance with aspects described herein. As illustrated by FIG. 7, the method 700 includes block 710 which involves fabricating a silicon substrate. The method 700 further involves block 720, which describes forming an aluminum nitride layer on the silicon substrate. The method 700 further involves block 730, which describes fabricating an electroacoustic stack on or above the aluminum nitride layer, the electroacoustic stack including a piezoelectric layer different from the aluminum nitride layer and a interdigital transducer. The piezoelectric layer includes a crystalline structure configured to excite a plate mode resonance.

Additional illustrative aspects of the disclosure include:

Aspect 1. An electroacoustic structure comprising: a substrate; an aluminum nitride layer formed on or above the substrate; and electrode layer formed on or above the aluminum nitride layer opposite the substrate; a piezoelectric layer formed on the electrode layer; and an interdigital transducer formed on the piezoelectric layer.

Aspect 2. The electroacoustic structure of Aspect 1, wherein the piezoelectric layer comprises a crystalline structure selected to excite Lamé mode resonance.

Aspect 3. The electroacoustic structure of any of Aspects 1 through 2, wherein the piezoelectric layer further comprises aluminum scandium-30 nitride (AlSc30N).

Aspect 4. The electroacoustic structure of any of Aspects 1 through 3, wherein the electroacoustic structure has a resonance frequency between 3 gigahertz (GHz) and 8 GHz.

Aspect 5. The electroacoustic structure of any of Aspects 1 through 4, wherein the aluminum nitride layer has a thickness approximately equal to a wavelength of the resonance frequency.

Aspect 6. The electroacoustic structure of any of Aspects 1 through 5, wherein the interdigital transducer comprises a plurality of copper (Cu) electrode fingers.

Aspect 7. The electroacoustic structure of any of Aspects 1 through 6, wherein the electrode layer comprises molybdenum (Mo).

Aspect 8. The electroacoustic structure of any of Aspects 1 through 7, further comprising a silicon oxide (SiO2) layer formed on or above the aluminum nitride layer.

Aspect 9. The electroacoustic structure of any of Aspects 1 through 8, wherein: the electroacoustic structure is a resonator of a filter circuit within a wireless transceiver of a wireless communication device; and the filter circuit is electrically coupled to an antenna of the wireless communication device.

Aspect 10. A method of fabricating an electroacoustic structure, the method comprising: fabricating a silicon substrate; forming an aluminum nitride layer on the silicon substrate; and fabricating an electroacoustic stack on or above the aluminum nitride layer, the electroacoustic stack comprising a piezoelectric layer different from the aluminum nitride layer and a interdigital transducer, wherein the piezoelectric layer comprises a crystalline structure configured to excite a plate mode resonance.

Aspect 11. The method of Aspect 10, wherein fabricating the piezoelectric stack comprises fabricating a lower interdigital transducer on the aluminum nitride layer; forming the piezoelectric layer on or above the lower interdigital transducer; and forming an upper interdigital transducer on the piezoelectric layer, where the interdigital transducer comprises the upper interdigital transducer and the lower interdigital transducer.

Aspect 12. The method of Aspect 10, wherein fabricating the electroacoustic stack further comprises: forming a silicon dioxide (SiO2) layer between the piezoelectric layer and the silicon substrate; and forming an electrode layer between the SiO2 layer and the piezoelectric layer.

Aspect 13. The method of Aspect 12, wherein the piezoelectric layer further comprises aluminum scandium-30 nitride (AlSc30N); and wherein the electroacoustic structure has a resonance frequency between 3 gigahertz (GHz) and 8 GHz.

Aspect 14. The method of Aspect 13, wherein the aluminum nitride layer is formed with a thickness approximately equal to a wavelength of the resonance frequency; and wherein the electrode layer comprises molybdenum (Mo).

Aspect 15. An electroacoustic structure comprising: a substrate; an aluminum nitride layer formed on or above the substrate; a electroacoustic stack formed on or above the aluminum nitride layer, the electroacoustic stack comprising a piezoelectric layer different from the aluminum nitride layer and a interdigital transducer, the piezoelectric layer comprises a crystalline structure configured to excite a plate mode resonance.

Aspect 16. The electroacoustic structure of Aspect 15, wherein the electroacoustic stack further comprises a silicon dioxide (SiO2) layer formed between the piezoelectric layer and the substrate.

Aspect 17. The electroacoustic structure of any of Aspects 15 through 16, further comprising an electrode layer formed between the SiO2 layer and the piezoelectric layer.

Aspect 18. The electroacoustic structure of any of Aspects 15 through 17, wherein the piezoelectric layer further comprises aluminum scandium-30 nitride (AlSc30N); and wherein the electrode layer comprises molybdenum (Mo).

Aspect 19. The electroacoustic structure of Aspect 15, wherein the interdigital transducer of the electroacoustic stack comprises a top interdigital transducer formed on or above the piezoelectric layer and a lower interdigital transducer formed under or below the piezoelectric layer.

Aspect 20. The electroacoustic structure of Aspect 19, wherein a dielectric material is positioned between electrode fingers of the lower interdigital transducer.

Aspect 21. An electroacoustic modulator comprising: a silicon substrate; an aluminum nitride high-speed layer formed on or above the silicon substrate; and a Lamé mode resonator structure formed on or above the aluminum nitride high-speed layer.

Aspect 22. A method for transmitting or receiving wireless signals using any apparatus above.

Aspect 23. A non-transitory computer readable medium comprising instructions that, when executed by a wireless communication device, causes the wireless communication device to transmit or receive signals using any apparatus or method described above.

Aspect 24. An apparatus comprising means for performing any operation described above.

Different aspects above refer to plate mode excitation or Lamé mode excitation. As described above, a Lamé mode is a type of plate mode. Implementations described herein can particularly apply to stacks with orientations and configurations for Lamé mode excitation. Similar implementations may apply generally to plate mode excitation with different stack orientation(s) and configuration(s).

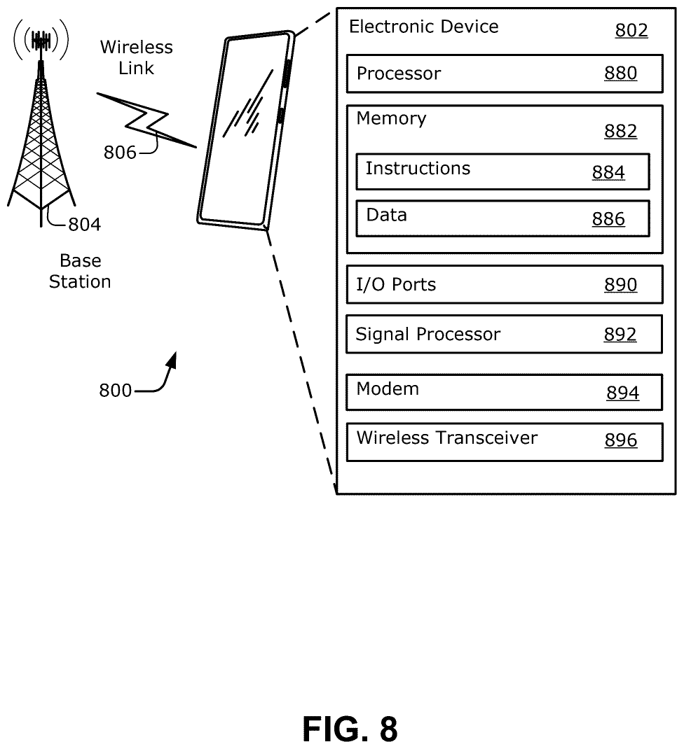

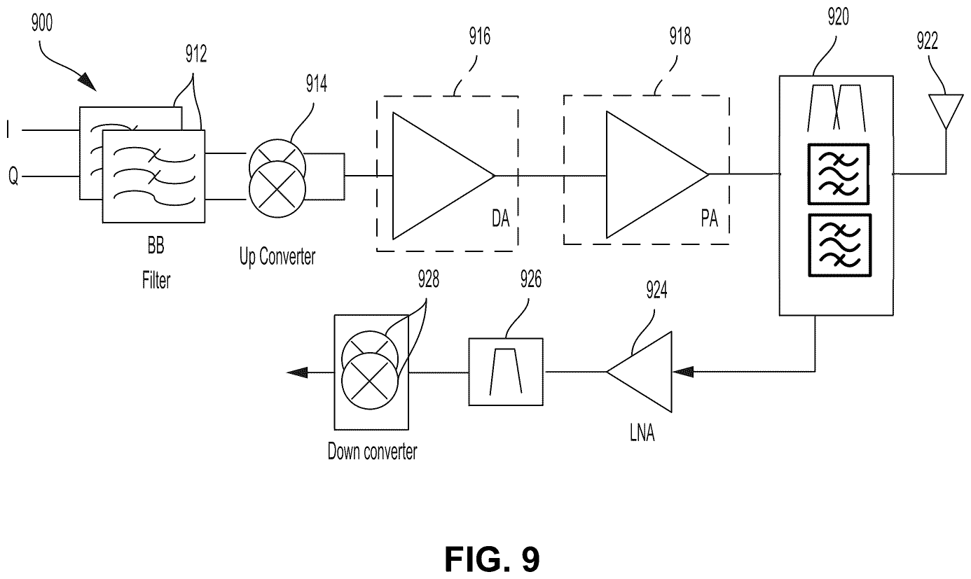

FIG. 8 is a diagram of an environment 800 that includes an electronic device 802 that includes a wireless transceiver 896 such as the transceiver circuit 900 of FIG. 9. The wireless transceiver 896 includes one or more filters with Lamé mode resonators in accordance with aspects described herein. The filters can be used in managing signals in above 3 gigahertz (GHz) sent by or received by antennas. In the environment 800, the electronic device 802 communicates with a base station 804 through a wireless link 806. As shown, the electronic device 802 is depicted as a smart phone. However, the electronic device 802 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, and so forth.

The base station 804 communicates with the electronic device 802 via the wireless link 806, which may be implemented as any suitable type of wireless link. Although depicted as a base station tower of a cellular radio network, the base station 804 may represent or be implemented as another device, such as a satellite, terrestrial broadcast tower, access point, peer to peer device, mesh network node, fiber optic line, another electronic device generally as described above, and so forth. Hence, the electronic device 802 may communicate with the base station 804 or another device via a wired connection, a wireless connection, or a combination thereof. The wireless link 806 can include a downlink of data or control information communicated from the base station 804 to the electronic device 802 and an uplink of other data or control information communicated from the electronic device 802 to the base station 804. The wireless link 806 may be implemented using any suitable communication protocol or standard, such as 3rd Generation Partnership Project Long-Term Evolution (3GPP LTE, 3GPP NR 5G), IEEE 802.11, IEEE 802.16, Bluetooth™, and so forth.

The electronic device 802 includes a processor 880 and a memory 882. The memory 882 may be or form a portion of a computer readable storage medium. The processor 880 may include any type of processor, such as an application processor or a multi-core processor, which is configured to execute processor-executable instructions (e.g., code) stored by the memory 882. The memory 882 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the memory 882 is implemented to store instructions 884, data 886, and other information of the electronic device 802, and thus when configured as or part of a computer readable storage medium, the memory 882 does not include transitory propagating signals or carrier waves.

The electronic device 802 may also include input/output ports 890. The I/O ports 890 enable data exchanges or interaction with other devices, networks, or users or between components of the device.

The electronic device 802 may further include a signal processor (SP) 892 (e.g., such as a digital signal processor (DSP)). The signal processor 892 may function similar to the processor and may be capable executing instructions and/or processing information in conjunction with the memory 882.

For communication purposes, the electronic device 802 also includes a modem 894, a wireless transceiver 896, and an antenna (not shown). The wireless transceiver 896 provides connectivity to respective networks and other electronic devices connected therewith using radio-frequency (RF) wireless signals and may include the transceiver circuit 900 of FIG. 9. The wireless transceiver 896 may facilitate communication over any suitable type of wireless network, such as a wireless local area network (LAN) (WLAN), a peer to peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

FIG. 9 is a functional block diagram of at least a portion of an example of a simplified wireless transceiver circuit 900 in which a wireless communication apparatus having filters with harmonic suppression in accordance with aspects described above may be employed. The transceiver circuit 900 is configured to receive signals/information for transmission (shown as I and Q values) which is provided to one or more base band filters 912. The filtered output is provided to one or more mixers 914. The output from the one or more mixers 914 is provided to a driver amplifier 916 whose output is provided to a power amplifier 918 to produce an amplified signal for transmission. The amplified signal is output to the antenna 922 through one or more filters 920 (e.g., duplexers if used as a frequency division duplex transceiver or other filters). The one or more filters 920 may include any filter circuit described herein, which can include one or more resonators in accordance with the details of the above description. The antenna 922 may be used for both wirelessly transmitting and receiving data. The transceiver circuit 900 includes a receive path through the one or more filters 920 to be provided to a low noise amplifier (LNA) 924 and a further filter 926 and then down-converted from the receive frequency to a baseband frequency through one or more mixer circuits 928 before the signal is further processed (e.g., provided to an analog digital converter and then demodulated or otherwise processed in the digital domain). There may be separate filters for the receive circuit (e.g., may have a separate antenna or have separate receive filters) that may be implemented using any filter circuit described herein.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. As part of such operations, methods described above can further include blocks to perform any additional functions described for operating an apparatus with harmonic suppression in accordance with examples described herein.

By way of example, an element, or any portion of an element, or any combination of elements described herein may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more example embodiments, the functions or circuitry blocks described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer. In some aspects, components described with circuitry may be implemented by hardware, software, or any combination thereof.

Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. An electroacoustic structure comprising:
a substrate;
an aluminum nitride layer formed on or above the substrate;
an electrode layer formed on or above the aluminum nitride layer opposite the substrate;
a piezoelectric layer formed on the electrode layer; and
an interdigital transducer formed on the piezoelectric layer.

2. The electroacoustic structure of claim 1, wherein the piezoelectric layer comprises a crystalline structure selected to excite Lamé mode resonance.

3. The electroacoustic structure of claim 2, wherein the piezoelectric layer further comprises aluminum scandium-30 nitride (AlSc30N).

4. The electroacoustic structure of claim 1, wherein the electroacoustic structure has a resonance frequency between 3 gigahertz (GHz) and 8 GHz.

5. The electroacoustic structure of claim 1, wherein the aluminum nitride layer has a thickness approximately equal to a wavelength of a resonance frequency of the electroacoustic structure.

6. The electroacoustic structure of claim 1, wherein the interdigital transducer comprises a plurality of copper (Cu) electrode fingers.

7. The electroacoustic structure of claim 1, wherein the electrode layer comprises molybdenum (Mo).

8. The electroacoustic structure of claim 1, further comprising a silicon oxide (SiO2) layer formed on or above the aluminum nitride layer.

9. The electroacoustic structure of claim 1, wherein:
the electroacoustic structure is a resonator of a filter circuit within a wireless transceiver of a wireless communication device; and
the filter circuit is electrically coupled to an antenna of the wireless communication device.

10. A method of fabricating an electroacoustic structure, the method comprising:
fabricating a silicon substrate;
forming an aluminum nitride layer on the silicon substrate; and
fabricating an electroacoustic stack on or above the aluminum nitride layer, the electroacoustic stack comprising a piezoelectric layer different from the aluminum nitride layer and a interdigital transducer, wherein the piezoelectric layer comprises a crystalline structure configured to excite a plate mode resonance.

11. The method of claim 10, wherein fabricating the electroacoustic stack comprises fabricating a lower interdigital transducer on the aluminum nitride layer;
forming the piezoelectric layer on or above the lower interdigital transducer; and
forming an upper interdigital transducer on the piezoelectric layer, where the interdigital transducer comprises the upper interdigital transducer and the lower interdigital transducer.

12. The method of claim 10, wherein fabricating the electroacoustic stack further comprises:
forming a silicon dioxide (SiO2) layer between the piezoelectric layer and the silicon substrate; and
forming an electrode layer between the SiO2 layer and the piezoelectric layer.

13. The method of claim 12, wherein the piezoelectric layer further comprises aluminum scandium-30 nitride (AlSc30N); and
wherein the electroacoustic structure has a resonance frequency between 3 gigahertz (GHz) and 8 GHz.

14. The method of claim 13, wherein the aluminum nitride layer is formed with a thickness approximately equal to a wavelength of the resonance frequency; and
wherein the electrode layer comprises molybdenum (Mo).

15. An electroacoustic structure comprising:
a substrate;
an aluminum nitride layer formed on or above the substrate; and
an electroacoustic stack formed on or above the aluminum nitride layer, the electroacoustic stack comprising a piezoelectric layer different from the aluminum nitride layer and a interdigital transducer, the piezoelectric layer having a crystalline structure configured to excite a plate mode resonance.

16. The electroacoustic structure of claim 15, wherein the electroacoustic stack further comprises a silicon dioxide (SiO2) layer formed between the piezoelectric layer and the substrate.

17. The electroacoustic structure of claim 16, further comprising an electrode layer formed between the SiO2 layer and the piezoelectric layer.

18. The electroacoustic structure of claim 17, wherein the piezoelectric layer further comprises aluminum scandium-30 nitride (AlSc30N); and
wherein the electrode layer comprises molybdenum (Mo).

19. The electroacoustic structure of claim 15, wherein the interdigital transducer of the electroacoustic stack comprises a top interdigital transducer formed on or above the piezoelectric layer and a lower interdigital transducer formed under or below the piezoelectric layer.

20. The electroacoustic structure of claim 19, wherein a dielectric material is positioned between electrode fingers of the lower interdigital transducer.
